(19) United States
(12) Patent Application Publication
(10) Pub. No.: US 2005/0244325 A1
(43) Pub. Date: Nov. 3, 2005

(54) Carbon nanotube, electron emission source including the same, electron emission device including the electron emission source,and method of manufacturing the electron emission device

(76) Inventors: Joong-Woo Nam, Suwon-si (KR); Jong-Hwan Park, Suwon-si (KR); Mee-Ae Ryu, Suwon-si (KR)

Correspondence Address: Robert E. Bushnell;Suite 300, 1522 K Street, N.W., Washington, DC, 20005, US

(21) Appl. No.: 11/117,462

(22) Filed: Apr. 29, 2005

(30) Foreign Application Priority Data
Apr. 29, 2004 (KR) 10-2004-0030258

(51) Int. Cl. H01L 29/06

(52) U.S. Cl. 423/414

(57) ABSTRACT

A carbon nanotube (CNT) with Raman spectrum having a G band and a D band, includes a ratio of a G band peak integral I_{G} and a D band peak integral I_{D} is 5 or greater. Further, there is an electron emission source including the CNT, an electron emission device including the electron emission source and a method of manufacturing the electron emission device. The electron emission source including the CNT has preferred current density, so the electron emission device using the electron emission source is highly reliable.

### CLAIM OF PRIORITY

This application makes reference to, incorporates the same herein, and claims all benefits accruing under 35 U.S.C. § 119 from an application for A CARBON NANOTUBE, AN EMITTER COMPRISING THE CARBON NANOTUBE AND AN ELECTRON EMISSION DEVICE COMPRISING THE EMITTER earlier filed in the Korean Intellectual Property Office on 29 Apr. 2004 and there duly assigned Serial No. 10-2004-0030258.

### BACKGROUND OF THE INVENTION

1. Field of the Invention

The present invention relates to a CNT (carbon nanotube), an electron emission source including the same, an electron emission device including the electron emission source, and a method of manufacturing the electron emission device, and more particularly, to a CNT with Raman spectrum having a G band and a D band, wherein a ratio of a G band peak integral (I_{G}) to a D band peak integral (I_{D}) is 5 or greater, an electron emission source including the CNT, an electron emission device including the electron emission source, and a method of manufacturing the electron emission device.

2. Description of the Related Art

An electron emission device includes an anode and a cathode. A voltage is applied between the anode and the cathode to form an electric field. As a result, an electron emission source of the cathode emits electrons. The electrons are collided with a phosphorous material of the anode to emit light.

A carbon-based material including a carbon nanotube (CNT), which has strong electron conductivity, has various advantages: strong conductivity, high field enhancement effect, a low work function, and excellent electron emitting characteristics. Furthermore, the carbon-based material can be operated at low voltage, and manufactured in a large area. Therefore, the carbon-based material is expected to be an ideal electron emission source of an electron emitting device.

U.S. Pat. No. 6,608,437 issued Kishi et al. for Electron-emitting Device, Electron Source and Image-forming Apparatus as well as Method of Manufacturing the Same disclose an electron emission device including a graphite film, of which Raman spectroscopic analysis using a laser light source with a wavelength of 514.5 nm (nanometers) and a spot diameter of 1 μm (microns) shows that the peak height at a Raman shift value of around 1580 cm⁻¹ is larger than that at a Raman shift value of around 1335 cm⁻¹ (centimeters⁻¹).

However, electron emission devices developed up to now, including the electron emission devices disclosed in the above-mentioned Patent, U.S. Pat. No. 6,608,437, have not met a desired level of electron emission characteristics. Accordingly, a CNT is required to obtain improved performance of electron emission sources.

### SUMMARY OF THE INVENTION

It is therefore, an object of the present invention to provide a carbon nanotube (CNT) capable of improving electron emission capability, an electron emission source including the same, an electron emission device including the electron emission source, and a method of manufacturing the electron emission device.

It is another object of the present invention to provide a CNT that has more defect-free carbon crystals than a conventional CNT, where the CNT can be provided in an electron emitting source or in an electron emitting source provided in an electron emission device.

It is yet another object of the present invention to provide CNT that has high reliability, where the CNT can be provided in an electron emitting source or in an electron emitting source provided in an electron emission device.

It is still another object of the present invention to provide a technique of manufacturing an electron emission device with CNT that has more defect-free carbon crystals than a conventional CNT and therefore a higher reliability that is easy to implement and cost effective while still being efficient.

According to an aspect of the present invention, there is provided a CNT with Raman spectrum having a G band and a D band, wherein a ratio of a G band peak integral (I_{G}) to a D band peak integral (I_{D}) is 5 or greater.

The ratio of a G band peak integral (I_{G}) to a D band peak integral (I_{D}) may be in the range of 5-7.

According to another aspect of the present invention, there is provided an electron emission source including a CNT with Raman spectrum having a G band and a D band, wherein a ratio of a G band peak integral (I_{G}) to a D band peak integral (I_{D}) is 5 or greater.

The electron emission source may have an emission current density of 100 μA/cm² (current density of microamperes per square centimeter) or greater at 5V/μm (voltage for unit area of volts per microns).

According to still another aspect of the present invention, there is provided an electron emission device including a substrate, a cathode electrode formed on the substrate, and an electron emission source electrically contacting the cathode electrode formed on the substrate and including a CNT with Raman spectrum having a G band and a D band, wherein a ratio of a G band peak integral (I_{G}) to a D band peak integral (I_{D}) is 5 or greater.

According to yet another aspect of the present invention, there is a method of manufacturing an electron emission device including: preparing a composition for preparing an electron emission source including a CNT with Raman spectrum having a G band and a D band, wherein a ratio of a G band peak integral (I_{G}) to a D band peak integral (I_{D}) is 5 or greater, and a vehicle; printing the composition for preparing an electron emission source on a substrate; and heat treating the printed composition for preparing an electron emission source.

A CNT according to the present invention has Raman spectrum of the CNT having a G band and a D band, wherein the ratio of the G band peak integral (I_{G}) to the D band peak integral (I_{D}) is 5 or greater, thereby having less defects than conventional CNTs. As a result, an electron emission device including an electron emission source including the CNT is highly reliable.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a sectional view illustrating an electron emission device according to an embodiment of the present invention;

FIG. 2 through 4 are Raman spectra of a carbon nanotube (CNT) according to an embodiment of the present invention and a conventional CNT, respectively; and

FIG. 5 illustrates current densities of an electron emission source including the CNT according to an embodiment of the present invention and an electron emission source including the conventional CNT.

### DETAILED DESCRIPTION OF THE INVENTION

The present invention provides a carbon nanotube (CNT) with Raman spectrum having a G band and a D band, wherein the ratio of a G band peak integral (I_{G}) to a D band peak integral (I_{D}) is 5 or greater.

Raman spectroscopy is used to analyze the structure of a CNT and in particular, is very useful for surface state analysis of the CNT. In Raman spectrum of the CNT, the G band peaks at a Raman shift value of around 1580 cm⁻¹ resulting from the SP² coordination of the CNT, and represents a defect-free carbon crystal. The D band peaks at a Raman shift value of around 1360 cm⁻¹ resulting from the SP³ coordination of the CNT, and represents a carbon crystal with defects. The G band peak integral and the D band peak integral is denoted by I_{G} and I_{D}, respectively.

In a Raman spectrum of the CNT according to an embodiment of the present invention, a ratio of a G band peak integral (I_{G}) to a D band peak integral (I_{D}) is 5 or greater, and preferably in the range of 5-7. If the ratio of a G band peak integral (I_{G}) to a D band peak integral (I_{D}) is less than 5, there may be no electron emission effect.

In Raman spectrum of the CNT according to the present invention, the G band may be a peak at a Raman shift value of a 1580±80 cm⁻¹ region and the D band may be a peak at a Raman shift value of a 1360±60 cm^{31 1} region. The frequency ranges related with the G band and the D band can be shifted depending on a laser light source used in the Raman analysis.

The CNT according to the present invention can be prepared by, for example, electric discharge, laser deposition, vapor phase growth, thermal vapor deposition, plasma chemical vapor deposition, or the like. Hereinafter, a method of manufacturing the CNT according to an embodiment of the present invention will be described, but is not limited thereto.

First, a catalytic metal on which a CNT is to grow is prepared. Examples of the catalytic metal include, for example, Co, Ni, Fe, and an alloy of these. Then, a catalytic metal film having a thickness of a few nanometers to few hundreds nanometers can be formed on a substrate composed of, for example, glass, quartz, silicon, Al₂O₃, or the like by using thermal deposition, electron beam deposition, or sputtering. Then, the catalytic metal film is etched to form nano-sized catalytic metal particles. The particles are separated from each other. Examples of an etching gas include ammonia, hydrogen, hydride, or the like. The etching gas severs the catalytic metal film along a grain boundary to form a uniform and high density collection of nano-sized catalytic metal particles separated from each other.

Alternately, the catalytic metal can be prepared using a zeolite support. In detail, the catalytic metal can be combined with the zeolite support by, for example, impregnation or ion exchange. In this case, Co/Y, Co/ZSM-5, or Fe/Y can be obtained. Such catalysts obtained using the zeolite support can be manufactured by, for example, using a Co-(Fe) acetate solution. In this case, the final amount of Co or Fe may be about 2.5% by weight.

Then, a carbon nanotube grows on the catalytic metal. A carbon supplying gas may be C₁₋₃ hydrocarbon gas such as acetylene, ethylene, ethane, propylene, propane, or methane. The CNT grows in general at 700-800° C. (Celsius). The carbon supplying gas can be supplied with a carrier gas or a dilute gas in order to control growing rate and time of the CNT. The carrier gas may be H or Ar. The dilute gas may be a hydride gas.

The CNT prepared in the above manner includes various impurities such as graphitic or amorphous carbon bundles, carbon particles, and catalytic metal particles. The carbon particles are extremely small pieces of carbon bundles, which are mainly attached to the surface of each CNT. When an electron emission source has the impurities, electron emission characteristics deteriorate. Accordingly, an additional refining process can be carried out after manufacturing the CNT, to remove the impurities. Examples of the refining process include ultrasonic washing, centrifuge, chemical sedimentation, filtering, chromatography, and the like. An embodiment of a method of refining the CNT according to the present invention will now be described, but is not limited thereto.

First, directly after synthesis, the CNT is pulverized by a grinder and a mixer. Then, the amorphous carbon is oxidized by an acid solution, thereby removed from the CNT. The acid solution can be KMnO₄, HCl, H₂SO₄, HNO₃, and the like. The acid solution is used to remove, for example, the amorphous carbon bundles from the CNT. Before using the acid solution, if needed, catalytic particles can be dissolved by using an etching solution composed of, for example, HF. The resulting CNT is filtered using a metal mesh, added with distilled water, dried, and the result is a refined CNT.

According to another embodiment of refining the CNT, directly after synthesis, the CNT is washed with an aqueous acid solution in a refining bath to separate impurities from the CNT. Next, it is filtered to remove the separated impurities, which can be carbon bundles, carbon particles, or catalytic metal bundles. The aqueous acid solution may be 2% nitric acid solution or 2% hydrochloric acid solution. Then, ultra-pure water is added to the refining bath to over-flow the acid aqueous solution, and then the bath is filtered through a metal mesh filter to remove impurities.

The filtered CNT is refined using a mixture of acetone and acid while being subject to supersonic vibration. The mixture may be a mixture of acetone, nitric acid, and hydrochloric acid, or a mixture of acetone, nitric acid, and acetic acid. In detail, acetone and ultra-pure water are added to the refining bath to over-flow the solution mixture of acetone and the acid solution. Acetone is added to the result, which is placed in supersonic wave washing equipment. The ultrasonic bath separates impurities, such as carbon bundles, carbon particles, or catalytic metal bundles, which are adhered to the surface of the CNT. The separated impurities are filtered from the CNT by a metal mesh filter.

The filtered CNT is dry-refined using a refining gas. Examples of the refining gas include ammonia, hydrogen, oxygen, a mixture of these; hydrochloric acid gas, nitric acid gas, acetic acid gas, and a mixture of these. By experiencing the above-mentioned refining processes, directly after synthesis, the CNT is completely free of carbon particles and catalytic metal bundles.

Meanwhile, the filtered CNT can be refined using other refining methods.

The present invention provides an electron emission source including a CNT with Raman spectrum having a G band and a D band, wherein a ratio of the G band peak integral (I_{G}) to the D band peak integral (I_{D}) is 5 or greater, and is preferably in the range of 5-7.

An electron emission source according to the present invention is formed by, for example, chemical vapor deposition or pasting. The pasting is performed using a composition for preparing an electron emission source. Pasting is more preferable to the chemical vapor deposition in terms of mass-production and manufacturing unit costs. When an electron emission source is formed by pasting, the electron emission source may further include the heat treatment result of a vehicle.

The electron emission source according to the present invention may have the current density of 100 μA/cm² or greater, and is preferably in the range of 500-1000 μA/cm². If the current density is less than 100 μA/cm² at 5 V/um, the brightness of the electron emission source decreases.

The present invention provides an electron emission device including a substrate, a cathode electrode formed on the substrate, and an electron emission source electrically contacting the cathode electrode and including a CNT with Raman spectrum having a G band and a D band, wherein a ratio of a G band peak integral (I_{G}) to a D band peak integral (I_{D}) is 5 or greater, and is preferably in the range of 5-7. The electron emission source of the electron emission device according to the present invention has a current density of 100 μA/cm² or greater at 5 V/um.

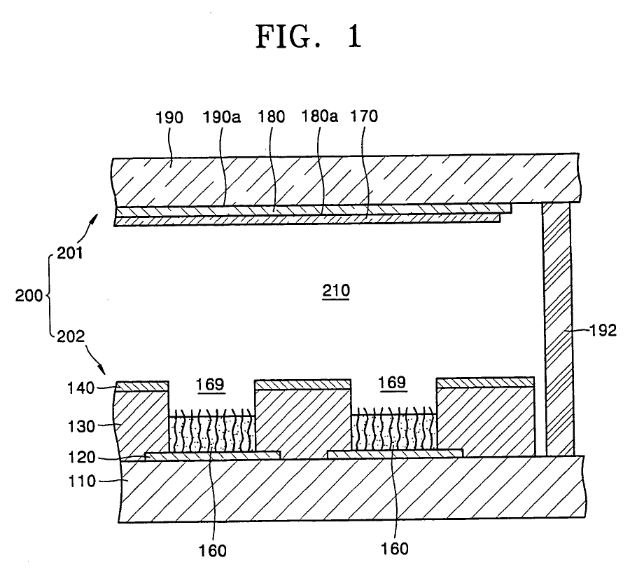

FIG. 1 illustrates an embodiment of the electron emission device including the electron emission source according to the present invention. Particularly, FIG. 1 illustrates schematically an electron emission device having a triode structure among various electron emission devices according to the present invention. Referring to FIG. 1, an electron emission device 200 includes an upper substrate 201 and a lower substrate 202. The upper substrate 201 includes a second substrate 190, an anode 180 disposed on a lower surface 190a of the second substrate 190, and a phosphor layer 170 disposed on a lower surface 180a of the anode 180.

The lower substrate 202 includes a first substrate 110 separated from the second substrate 190 with a predetermined distance to form an inner space, and facing the second substrate 190; a cathode 120 arranged in strips on the first substrate 110; a gate electrode 140 being arranged in strips to be perpendicular to the cathode 120, an insulating layer 130 interposed between the gate electrode 140 and the cathode 120; an electron emission source hole 169 formed on a portion of the insulating layer 130 and the gate electrode 140; and an electron emission source 160 disposed within the electron emission source hole 169, electrically connected to the cathode 120, and positioned lower than the gate electrode 140. The electron emission source 160 includes the above-mentioned CNT.

The upper substrate 201 and the lower substrate 202 are maintained in a vacuum condition lower than the atmospheric pressure. A spacer 192 is interposed between the upper substrate 201 and the lower substrate 202 to support a pressure between the upper substrate 201 and the lower substrate 202 generated by the vacuum, and to partition a light emitting space 210.

High voltage required to accelerate the electron emitted from the electron emission source 160 is applied to the anode 180. Such electrons collide with the phosphor layer 170 at high speed. Due to the collision, a phosphorous material of the phosphor layer is excited by the electrons. The excited phosphorous material is changed form a high energy level to a low energy level, thus emitting, for example, visible light.

Electrons can be easily emitted from the electron emission source 160 by the gate electrode 140. The insulating layer 130 partitions the electron emission source hole 169. The electron emission source 160 is insulated from the gate electrode 140 by the insulating layer 130.

Although the present embodiment is described with reference to the electron emission device having a triode structure as is shown in FIG. 1, the present invention may relate to an electron emission device having various structures, for example, a diode structure. In addition, the present invention may also relate to an electron emission device including a gate electrode disposed below a cathode electrode, and an electron emission device including a grid or mesh. In the last case, the grid or mesh prevents a gate electrode and/or a cathode from being damaged by an electrical arc, which is assumed to be generated by a discharging phenomenon, and guarantees to collect electrons emitted from an electron emission source.

The present invention provides a method of manufacturing an electron emission device, the method including preparing a composition for preparing an electron emission source including the CNT according to the present invention, and a vehicle; printing the composition for preparing an electron emission source on a substrate; and heat treating the printed composition for preparing an electron emission source. An embodiment of a method of manufacturing the electron emission device according to the present invention will now be described.

First, a composition for preparing an electron emission source is prepared. The composition for preparing an electron emission source includes a CNT and a vehicle.

The CNT emits electrons, and may be the above-mentioned CNT with Raman spectrum having a G band and a D band, wherein a ratio of a G band peak integral (I_{G}) to a D band peak integral (I_{D}) is 5 or greater. The CNT may be an amount of 0.1-30% by weight, and preferably 5-20% by weight based on the composition for preparing an electron emission source.

The vehicle controls viscosity and printing property of the composition for preparing an electron emission source. The vehicle includes a resin component and a solvent component. Examples of the resin component include a cellulose-based resin, an acryl-based resin, a vinyl-based resin, and the like. The cellulose-based resin may be ethyl cellulose, nitro cellulose, or the like. The acryl-based resin may be polyester acrylate, epoxy acrylate, or urethane acrylate. The solvent component may be butyl carbitol acetate (BCA), terpineol (TP), toluene, texanol, butyl carbitol (BC), or the like.

The resin component may be in an amount of 5-60% by weight based on the composition for preparing the electron emission source. The solvent component may be in an amount of 40-80% by weight based on the composition for preparing the electron emission source.

The composition for preparing an electron emission source may further include a filler, an inorganic binder, a photosensitive resin and a photo initiator, a viscosity improver, a resolution improver, or the like.

The filler improves the conductivity of the CNT that adheres to the substrate. Examples of the filler include Ag, Al, Pd, and the like.

The inorganic binder improves the adhesive force between the CNT and the substrate. Examples of the inorganic binder include glass frit, silane, SOG, alumina, zirconia, or the like. The organic binder may have an amount of 1-10% by weight based on the composition for preparing an emitter, but is not limited thereto.

The photosensitive resin can be cross-linked when exposed to light. Examples of the photosensitive resin include poly(methyl methacrylate) (PMMA), trimethylolpropane triacrylate (TMPTA), methyl acrylate, and the like. The photosensitive resin may have an amount of 3-40% by weight based on the composition for preparing the electron emission source.

The photo initiator initiates the cross-linking of the photosensitive resin. The photo initiator may be an acrylate-based monomer, a benzophenone-based monomer, an acetophenone-based monomer, a tioxanthone-based monomer, or the like. Preferably, the photo initiator may be epoxy acrylate, polyester acrylate, 2,4-diethyloxanthone, or 2,2-dimethoxy-2-phenylacetophenone, but is not limited thereto. The amount of the photo initiator is in the range of 0.05-10% by weight.

The composition for preparing an electron emission source having the above-mentioned components and contents may have a viscosity of, for example, 5,000-50,000 cps (centipoises) in consideration with printing property.

The composition for preparing an electron emission source is printed on a substrate. Here, the term “substrate” refers to a substrate on which the electron emission source is formed. For example, in an electron emission device including a gate electrode interposed between an anode electrode and a cathode electrode, “substrate” refers to a cathode unit formed on a supporting substrate. However, in an electron emission device including a gate electrode formed below a cathode electrode, “substrate” refers to a gate insulating layer formed on a gate electrode that is formed on a supporting substrate. The substrate can be easily recognized by those skilled in the art.

The printing process can be different depending on whether the composition for preparing an electron emission source includes a photosensitive resin or not. When the composition for preparing an electron emission source includes the photosensitive resin, an additional photoresist pattern is unnecessary. In detail, the composition for preparing an electron emission source is printed on the substrate, and is then exposed and developed depending on the region. On the other hand, when the composition for preparing an electron emission source does not include the photosensitive resin, a photolithography process in which an additional photoresist film pattern is used is necessary. In detail, a photoresist film pattern is formed using a photoresist film, and then the composition for preparing an electron emission source is printed using the photoresist film pattern.

Then, the printed composition for preparing the electron emission source is heat treated, thereby improving the adhesive force between the CNT and the substrate, enhancing durability by melting and solidification of at least one binder, and minimizing the outgassing. The proper temperature for the heat treating must be determined with consideration to the volatilizing temperature of the vehicle. The temperature of the heat treatment is conventionally at 350-500° C. (Celsius), and is preferably 450° C. If the temperature of the heat treatment is lower than 350° C., the vehicle does not sufficiently volatilize. If the temperature of the heat treatment exceeds 500° C., the CNT can be damaged.

Then, optionally the heat treatment result is activated. According to an embodiment of the activating step, an electron emission source surface treating agent is coated on the heat treatment result, baked to form a layer of the electron emission source surface treating agent, and detached from the surface of the electron emission source. The electron emission source surface treating agent may include, for example, a polyimide-based polymer. According to another embodiment of the activating step, an adhesive unit with adhesive force is formed on a surface of a roller that is operated by a predetermined driving source, and then a surface of the heat treatment result is pressed with a predetermined pressure using the roller. During the activating step, the CNT is exposed to a surface of the electron emission source or, and the vertical arrangement of the CNT can be adjusted.

The present invention will be described in further detail with reference to the following examples. The following examples are for illustrative purposes and are not intended to limit the scope of the invention.

### SAMPLE 1

A Co/ZSM-5 catalyst containing 2.5% by weight of Co was prepared using a Co-acetate solution. Then, acetylene was added thereto to grow a CNT at 750° C. (Celsius). The grown CNT was recovered, pulverized, washed with HCl, H₂SO₄, and HNO₃, filtered, and dried to produce a final CNT.

Raman analysis of the final CNT was performed using a Raman spectrometer having a magnification of 20×, an exposure time of 60 sec (seconds), and a laser with a power of 1.5 mW (milliwatt).

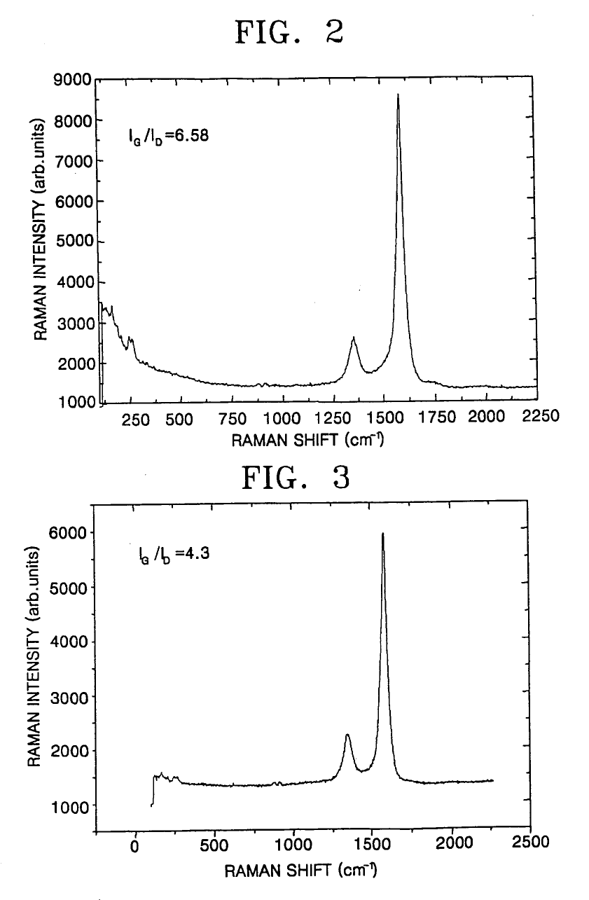

A Raman spectrum of the CNT is illustrated in FIG. 2. Referring to FIG. 2, an integral ratio of a peak at a Raman shift value of a 1580 cm⁻¹ region to a peak at a Raman shift value of a 1360 cm⁻¹ region is 6.58.

The CNT, glass frit, ethyl cellulose, methyl acrylic acide, butyl carbitol acetate were mixed to prepare a composition for preparing an electron emission source having a viscosity of 25,000 cps (centipoises). A substrate was coated with the composition for preparing an electron emission source. Then, parallel exposure equipment was used to irradiate the composition for preparing an electron emission source with an exposure energy of 2000 mJ/cm² (milli-Joule per square centimeter) using a pattern mask. After exposure, the irradiated electron emission source forming composition was developed by developing agent, and heat-treated at 450° C. to produce an electron emission source. The electron emission source according to Sample 1 is referred to as Sample 1, hereinafter.

### SAMPLE A

First, Raman analysis of a multi-walled CNT (MWCNT) CNT purchased from ILJINNANOTECH.Co. was carried out in the same manner as illustrated in Sample 1. A Raman spectrum of the CNT is illustrated in FIG. 3. Referring to FIG. 3, the integral ratio of a peak at a Raman shift value of a 1580 cm⁻¹ region to a peak at a Raman shift value of a 1360 cm⁻¹ region was 4.3.

Next, an electron emission source was manufacture in the same manner as in Sample 1, except that the MWCNT purchased from ILJINNANOTECH.Co. was used instead of the CNT described in Sample 1. The electron emission source manufactured in the manner described above is referred to as Sample A, hereinafter.

### SAMPLE B

Raman analysis of MWNT CNT (purchased from ILJINNANOTECH.Co) different from the CNT used in Sample A was carried out in the same manner as illustrated in Sample 1. A Raman spectrum of the MWNT CNT is illustrated in FIG. 4. Referring to FIG. 4, the integral ratio of a peak at a Raman shift value of a 1580 cm⁻¹ region to a peak at a Raman shift value of a 1360 cm⁻¹ region was 2.3.

Next, an electron emission source was manufactured in the same manner as in Sample 1, except that the MWNT CNT purchased from ILJINNANOTECH.Co. was used instead of the CNT described in Sample 1. The electron emission source manufactured in the manner described above is referred to as Sample B, hereinafter.

### MEASUREMENT EXAMPLE 1

Current Density Measurement

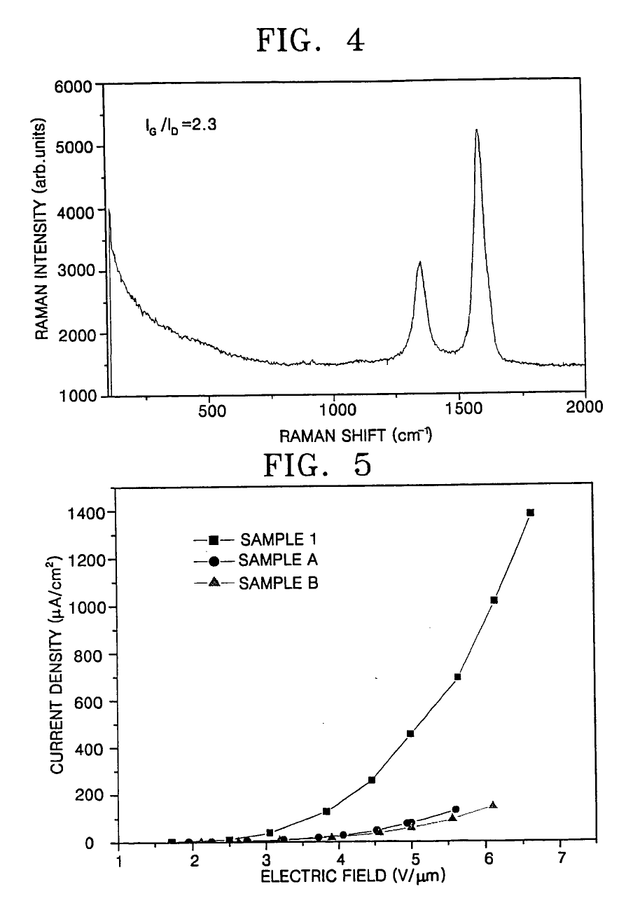

Current densities of Sample 1 and Samples A and B were measured and the results are shown in FIG. 5. Referring to FIG. 5, the current density of Sample 1 at 5V/um was 400 μA/cm², and the current density of Samples A and B were about 50 μA/cm². The current density plot of Sample 1 was confirmed to have much larger gradient than that of Samples A and B.

### SAMPLE 2

A transparent ITO (indium-tin oxide) cathode electrode was formed on a first substrate. A polyimide insulating layer was formed to cover the cathode electrode. An electron emission source formation region was formed in the insulating layer to expose a portion of the cathode electrode surface. Then, a Cr gate electrode was formed in strips on an upper surface of the insulating layer, thereby being perpendicular to the cathode electrode. Next, an electron emission source was formed in the electron emission source formation region according to the method of manufacturing an electron emission source illustrated in Sample 1. Finally, a second substrate including a fluorescent film, and a spacer maintaining a cell gap between the first substrate and the second substrate are formed.

In Raman spectrum of the CNT according to the present invention, a ratio of the G band peak integral (I_{G}) to the D band peak integral (I_{D}) is 5 or greater. So, the CNT has more defect-free carbon crystals than a conventional CNT. As a result, an electron emission device including an electron emission source including the CNT has high reliability.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A carbon nanotube with Raman spectrum having a G band and a D band, with a ratio of a G band peak integral (I_{G}) and a D band peak integral (I_{D}) being at least 5.

2. The carbon nanotube of claim 1, wherein the ratio of the G band peak integral (I_{G}) and the D band peak integral (I_{D}) is in a range from and including 5 to and including 7.

3. The carbon nanotube of claim 1, wherein the ratio of the G band peak integral (I_{G}) and the D band peak integral (I_{D}) is in a range between 5 and 7.

4. The carbon nanotube of claim 1, wherein the G band of the Raman spectrum represents a peak at a Raman shift value of a 1580±80 cm⁻¹ region and the D band of Raman spectrum represents a peak at a Raman shift value of a 1360±60 cm⁻¹ region.

5. The carbon nanotube of claim 4, wherein the frequency ranges related with the G band and the D band being shifted according to a laser light source used in the Raman analysis.

6. An electron emission source, comprising a carbon nanotube with the Raman spectrum having a G band and a D band, wherein a ratio of a G band peak integral (I_{G}) and a D band peak integral (I_{D}) is at least 5.

7. The electron emission source of claim 6, wherein the ratio of the G band peak integral (I_{G}) and the D band peak integral (I_{D}) is in a range from and including 5 to and including 7.

8. The electron emission source of claim 6, wherein the ratio of the G band peak integral (I_{G}) and the D band peak integral (I_{D}) is in a range between 5-7.

9. The electron emission source of claim 6, further comprised of a current density being greater than 100 μA/cm² at 5V/um.

10. The electron emission source of claim 6, wherein the current density is greater than approximately 100 μA/cm² at approximately 5V/um.

11. The electron emission source of claim 10, wherein the current density is in a range of 500-1000 μA/cm².

12. The electron emission source of claim 7, wherein the current density is greater than approximately 100 μA/cm² at approximately 5V/um.

13. An electron emission device comprising:
a substrate;
a cathode electrode formed on said substrate; and
an electron emission source comprising a carbon nanotube with a Raman spectrum having a G band and a D band, with a ratio of a G band peak integral (I_{G}) and a D band peak integral (I_{D}) is at least 5.

14. The electron emission device of claim 13, wherein the ratio of the G band peak. integral (I_{G}) and the D band peak integral (I_{D}) is in a range from and including 5 to and including 7.

15. The electron emission device of claim 13, wherein said electron emission source has the current density of 100 μA/cm² or greater at 5V/um.

16. The electron emission device of claim 15, wherein said electron emission source has a current density in a range of 500-1000 μA/cm².

17. A method of manufacturing an electron emission device, comprising:
preparing a composition for preparing an electron emission source including a carbon nanotube with Raman spectrum having a G band and a D band, with a ratio of a G band peak integral (I_{G}) and a D band peak integral (I_{D}) being at least 5, and a vehicle;
printing the composition for preparing an electron emission source on a substrate; and
heat treating said printed electron emission source forming composition.

18. The method of claim 17, wherein the composition for preparing said electron emission source further comprises a photosensitive resin or a mixture of a photosensitive resin and a photo initiator, and the printing of the composition for preparing an electron emission source comprises coating the substrate with the composition for preparing an electron emission source and performing exposure and development depending on a predetermined electron emission source formation region.
